(19) United States
(12) Patent Application Publication
(10) Pub. No.: US 2026/0282829 A1
(43) Pub. Date: Sep. 17, 2026

(54) ELECTROSTATIC CHUCK

(71) Applicant: TOTO LTD., Fukuoka (JP)

(72) Inventors: Takashi TAMADA, Fukuoka (JP); Jun SHIRAISHI, Fukuoka (JP); Hitoshi SASAKI, Fukuoka (JP)

(73) Assignee: TOTO LTD., Fukuoka (JP)

(21) Appl. No.: 19/530,071

(22) Filed: Feb. 4, 2026

(30) Foreign Application Priority Data
Mar. 17, 2025 (JP) 2025-042650

(51) Int. Cl. H10P 72/72; H01J 37/32

(52) U.S. Cl. CPC H10P 72/722; H01J 37/32724; H01J 2237/334

(57) ABSTRACT

An electrostatic chuck 10 includes a dielectric substrate 100 and a base plate 200 including a coolant flow path 250 formed therein through which a coolant passes. In the electrostatic chuck 10, the dielectric substrate 100 and the base plate 200 are joined to each other, and the coolant flow path 250 is a groove G that is formed on a surface 210 on the dielectric substrate 100 side of the base plate 200.

### CROSS-REFERENCE TO RELATED APPLICATION

This application is based upon and claims the benefit of priority from Japanese Patent Application No. 2025-042650 filed on March 17, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate inside which an attraction electrode is provided and a base plate which supports the dielectric substrate, and these are joined to each other. When a voltage is applied to the attraction electrode, an electrostatic force is generated, and the wafer placed on the dielectric substrate is attracted and held.

During a process such as etching, it is necessary to cool the wafer and maintain a temperature thereof at an appropriate temperature. For this reason, as described in Japanese Patent Laid-Open No. 2020-161597, a coolant flow path through which a coolant flows is formed in the base plate.

### SUMMARY

The dielectric substrate and the base plate are joined to each other via a resin material such as a silicone adhesive, for example. The coolant flow path is formed inside the base plate. Due to this, heat from the wafer is transferred to the coolant via the dielectric substrate, a joining layer made of a resin material, and the base plate, and the heat is exhausted to the outside together with the coolant. In other words, the coolant indirectly cools the dielectric substrate via the joining layer made of a resin material and the base plate, instead of directly cooling the dielectric substrate.

In such a configuration, to efficiently cool the wafer and the like by the coolant, it has been necessary to form the base plate with a metallic material or to mix a filler such as alumina into the joining layer made of a resin material. However, there is a limit to increasing cooling efficiency by such contrivances.

In recent years, an output of plasma used for etching and the like has been increasing. For this reason, it is considered that efficiently cooling the wafer and maintaining a temperature thereof at an appropriate temperature will become even more difficult in the future.

The present invention has been made in view of such a problem and aims at providing an electrostatic chuck capable of efficiently cooling a wafer.

To solve the above-described problem, an electrostatic chuck according to the present invention includes a dielectric substrate including a placement surface on which an object to be attracted is placed, and a base plate including a coolant flow path formed therein through which a coolant flows. In this electrostatic chuck, the dielectric substrate and the base plate are joined to each other, and the coolant flow path is a groove formed on a surface on the dielectric substrate side of the base plate.

In the electrostatic chuck having such a configuration, the coolant passing through the coolant flow path directly cools the dielectric substrate without passing through the joining layer made of a resin

material or the base plate. Thus, the wafer can be efficiently cooled as compared with configurations in the related art.

In the electrostatic chuck having the above-described configuration, it is not necessary to use, as a material of the base plate, a material having a high thermal conductivity such as aluminum, for example. Due to this, an advantage can also be obtained in that a degree of freedom in selecting a material of the base plate can be increased.

According to the present invention, it is possible to provide an electrostatic chuck capable of efficiently cooling a wafer.

### BRIEF DESCRIPTION OF THE DRAWINGS

FIG. 1 is a cross-sectional view schematically illustrating a configuration of an electrostatic chuck according to a first embodiment;

FIG. 2 is a diagram for explaining a method of manufacturing the electrostatic chuck;

FIG. 3 is a diagram illustrating a configuration of a base plate of the electrostatic chuck according to the first embodiment; and

FIG. 4 is a cross-sectional view schematically illustrating a configuration of a part of an electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

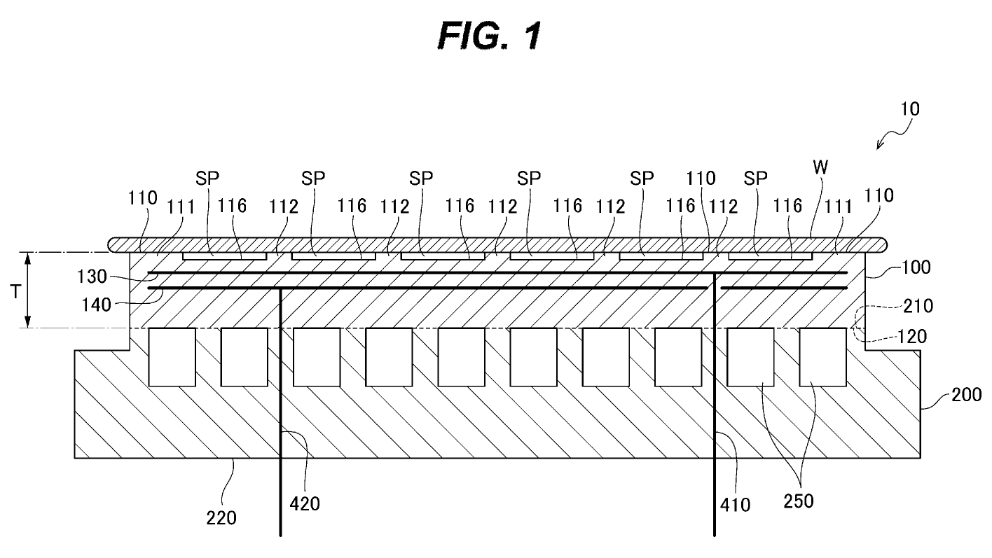

FIG. 1 is a cross-sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 is formed of, for example, a material containing highly pure alumina (Al₂O₃) as a principal component. A ceramic purity or type, an additive, or the like in the dielectric substrate 100 may be appropriately set by taking into account plasma resistance or the like needed for the dielectric substrate 100 in the semiconductor manufacturing apparatus.

In the present specification, the term "principal component" refers to a compound that is confirmed to be contained in a target object in a relatively larger amount than any other compound contained therein, when quantitative or semi-quantitative analysis is performed on the target object such as the dielectric substrate 100 by X-ray Diffraction (XRD). A ratio occupied by alumina as the principal component is larger than 50% in the dielectric substrate 100 of the present embodiment. The ratio is more preferably equal to or larger than 90%, and even more preferably equal to or larger than 95%.

When alumina is used as a material of the dielectric substrate 100 as in the present embodiment, it is preferable that a purity of alumina used as a raw material in the dielectric substrate 100 is set to be equal to or larger than 99.5%, or equal to or larger than 99.9%. By increasing the purity of alumina to such a level, it is possible to sufficiently ensure durability of the dielectric substrate 100 against plasma. A volume resistivity of the dielectric substrate 100 is preferably set to be equal to or larger (higher) than 1×10¹⁴ Ω -cm in a case of a Coulomb-force type electrostatic chuck, and is preferably set to fall within a range of 1×10 to 1×10¹² Ω-cm in a case of a Johnsen-Rahbek-force type electrostatic chuck.

A surface 110 on an upper side in FIG. 1 in the dielectric substrate 100 serves as a "placement surface" on which the wafer W is placed. A surface 120 on a lower side in FIG. 1 in the dielectric substrate 100 serves as a "surface to be joined" which is joined to the base plate 200 which will be described later. A perspective in a case where the electrostatic chuck 10 is viewed from the surface 110 side along a direction perpendicular to the surface 110 will also be hereinafter expressed as "top view".

An attraction electrode 130 is embedded inside the dielectric substrate 100. The attraction electrode 130 is a thin planar (plate-like) layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line 410, an electrostatic force is generated between the surface 110 and the wafer W, and according to this, the wafer W is attracted and held. The single attraction electrode 130 may be provided as so-called a "monopolar" electrode as in the present embodiment, but may also include two attraction electrodes as so-called "bipolar" electrodes. The attraction electrode 130 corresponds to a "conductor layer" provided inside the dielectric substrate 100.

In FIG. 1, the feed line 410 is entirely illustrated in a simplified manner. A portion of the feed line 410 inside the dielectric substrate 100 is configured as an elongated via (hole) filled with a conductor, for example, and a feed terminal is provided at a lower end thereof. A portion of the feed line 410 penetrating the base plate 200 is a rod-shaped metal whose one end is connected to the above-described feed terminal. A through hole which is not illustrated in the drawing for inserting the metal is formed in the base plate 200. As a configuration of the feed line 410 for applying a voltage to the attraction electrode 130, various well-known configurations can be adopted in addition to the above-described configuration.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When a high-frequency alternating-current voltage is applied between these counter electrodes, plasma is generated on the upper side of the wafer W and used for processing such as film deposition and etching on the wafer W.

Similarly to the attraction electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded at a position closer to the surface 120 side than the attraction electrode 130. Similarly to the attraction electrode 130, the RF electrode 140 is arranged so as to be parallel to the surface 110. The RF electrode 140 is a single electrode which is substantially circular in top view. In top view, a center of the RF electrode 140 matches a center of the dielectric substrate 100. The RF electrode 140 corresponds to another "conductor layer" provided inside the dielectric substrate 100. In the present embodiment, a plurality of conductor layers including the attraction electrode 130 and the RF electrode 140 are provided at height positions different from each other.

A feed line 420 is connected to the RF electrode 140. The feed line 420 constitutes an electric circuit for applying a voltage to the RF electrode 140 from the outside. In FIG. 1, the feed line 420 is entirely illustrated in a simplified manner. A portion of the feed line 420 inside the dielectric substrate 100 is configured as an elongated via (hole) filled with a conductor, for example, and a feed terminal is provided at a lower end thereof. A portion of the feed line 420 penetrating the base plate 200 is a rod-shaped metal whose one end is connected to the above-described feed terminal. A through hole which is not illustrated in the drawing for inserting the metal is formed in the base plate 200. As a configuration of the feed line 420 for applying a voltage to the RF electrode 140, various well- known configurations can be adopted in addition to the above-described configuration.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 serves as a part of the surface 110 and abuts against the wafer W. The distal end of the seal ring 111 can be referred to as a part on an outermost circumferential side on the surface 110 which serves as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 is a part of the surface 110 and abuts against the wafer W. By providing the plurality of thus configured dots 112, warping of the wafer W is reduced.

In order that the helium gas supplied from a gas hole which is not illustrated in the drawing be rapidly supplied to each part of the space SP, a groove may be formed in the bottom 116. It is preferable that the groove be formed to pass through a position of the gas hole.

Additionally, after forming a plurality of gas holes in the dielectric substrate 100, a distribution flow path for distributing the helium gas to the respective gas holes may be formed inside the electrostatic chuck 10. The distribution flow path may be formed as a groove on the surface 120 of the dielectric substrate 100, may be formed in a joining layer 300 described later, may be formed as a groove on a surface 210 of the base plate 200, which will be described next, and may also be formed inside the base plate 200.

The base plate 200 is a substantially disk-shaped member which supports the dielectric substrate 100. Similarly to the dielectric substrate 100, the base plate 200 is formed of a material containing alumina (Al₂O₃) as a principal component. The surface 210 on the dielectric substrate 100 side in the base plate 200 serves as a "surface to be joined" which is joined to the surface 120 of the dielectric substrate 100.

The surface 120 of the dielectric substrate 100 is joined to the surface 210 of the base plate 200 by solid-phase joining. The term "solid-phase joining" refers to a joining method in which two members are joined while being pressurized and heated in a state where surfaces to be joined of the two members are brought into direct contact with each other, or are caused to abut against each other via a solid-phase joining material interposed therebetween. However, a temperature during heating is lower than melting points of the respective members and the joining material. Accordingly, during joining, the respective members and the joining material remain in a solid phase and do not become a liquid phase.

As a method for solid-phase joining, various well-known methods can be used. For example, after bringing the surface 120 of the dielectric substrate 100, which is a sintered body, and the surface 210 of the base plate 200, which is also a sintered body, into a state where they directly abut against each other or abut against each other via a joining material, the surface 120 and the surface 210 can be joined to each other by solid-phase joining by performing processing of heating and pressurizing so as to reach predetermined temperature and pressure. This processing is performed in a vacuum or under a reducing atmosphere. During the processing, temperatures of the dielectric substrate 100 and the base plate 200 may be set to be lower than their respective sintering temperatures.

In the present embodiment, the surface 120 of the dielectric substrate 100 is solid-phase joined to the surface 210 of the base plate 200 in a state where they directly abut against each other without interposing another joining material therebetween. Molecules constituting the base plate 200 have entered a portion of the dielectric substrate 100 in the vicinity of the surface 120 by solid-phase diffusion. Additionally, molecules constituting the dielectric substrate 100 have entered a portion of the base plate 200 in the vicinity of the surface 210 by solid-phase diffusion. Such solid-phase diffusion of molecules as described above may occur bidirectionally between the dielectric substrate 100 and the base plate 200, but may occur in only one direction. In this manner, by causing solid-phase diffusion of molecules beyond the surfaces to be joined in one direction or in both directions, the dielectric substrate 100 and the base plate 200 are firmly joined to each other. Such a joining aspect is also referred to as "diffusion joining".

In this manner, in the present embodiment, the dielectric substrate 100 and the base plate 200 are joined to each other by solid-phase joining. As compared with a case where they are joined to each other via a resin material, it is possible to enhance durability of a joined portion against plasma. Additionally, as compared with a case where they are joined to each other via a resin material, it is possible to enhance thermal conductivity.

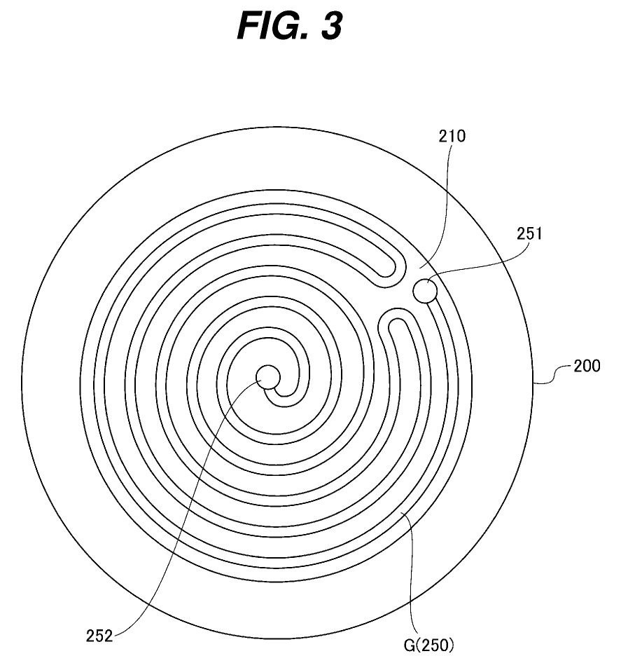

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP and the dielectric substrate 100, and the heat is exhausted to the outside together with the coolant. The supply and exhaustion of the coolant to and from the coolant flow path 250 are performed via holes 251 and 252 (which are not illustrated in FIG. 1; refer to FIG. 3) opening in a surface 220 opposite to the surface 210 in the base plate 200.

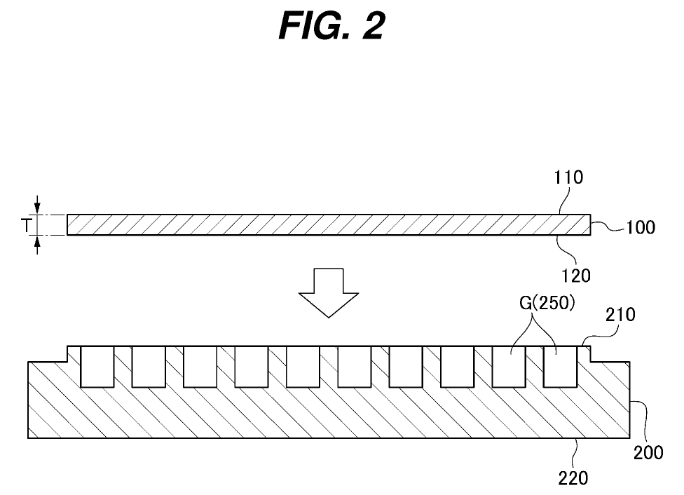

A method for manufacturing the electrostatic chuck 10 will be briefly described. First, the dielectric substrate 100 and the base plate 200 illustrated in FIG. 2 are prepared, respectively. A configuration of the dielectric substrate 100 is the same as the configuration described above. In FIG. 2, the dielectric substrate 100 is illustrated in a simplified manner, and the seal ring 111, the attraction electrode 130, and the like are not illustrated. The seal ring 111, the dot 112, and the like may be formed on the dielectric substrate 100 before joining the dielectric substrate 100 and the base plate 200, or after the joining thereof.

In FIG. 2, the base plate 200 is also illustrated in a simplified manner, and through holes and the like for inserting the feed lines 410 and 420 are not illustrated.

A groove G is formed on the surface 210 of the base plate 200. The groove G is a bottomed groove that is formed so as to recess a part of the surface 210 toward the surface 220 side, and its internal space finally becomes the coolant flow path 250.

FIG. 3 illustrates a configuration of the base plate 200 before being joined to the dielectric substrate 100 in top view. As illustrated in FIG. 3, the holes 251 and 252 are formed in the base plate 200. The holes 251 and 252 are circular through holes formed so as to penetrate the entire base plate 200 in a direction perpendicular to the surface 210. Of the holes 251 and 252, respective openings formed on the surface 220 side serve as an inlet and an outlet for the coolant.

The groove G connects the hole 251 and the hole 252 and is formed so as to extend along a path passing through almost the entirety of the base plate 200 in top view. In the present embodiment, the coolant is supplied from the surface 220 side to the hole 251. The coolant which has passed through the coolant flow path 250 (groove G) to be used for cooling the wafer W is discharged from the hole 252 to the surface 220 side.

After preparing the dielectric substrate 100 and the base plate 200, each having the configuration as described above, as illustrated in FIG. 2, the surface 120 of the dielectric substrate 100 is caused to abut against the surface 210 of the base plate 200, and these are joined to each other by solid-phase joining. Due to this, the internal space of the groove G is defined by an inner surface of the groove G and the surface 120 of the dielectric substrate 100, and becomes the coolant flow path 250.

As described above, the electrostatic chuck 10 according to the present embodiment has a configuration in which the groove G formed on the surface 210 on the dielectric substrate 100 side of the base plate 200 is used as the coolant flow path 250. In this configuration, the coolant passing through the coolant flow path 250 flows while being in direct contact with the dielectric substrate 100. Since the dielectric substrate 100 is directly cooled by the coolant, the wafer W can be efficiently cooled.

In an electrostatic chuck having a conventional configuration, the dielectric substrate 100 and the base plate 200 are joined to each other via a resin material such as a silicone adhesive, for example. Additionally, the coolant flow path 250 is formed inside the base plate 200 (instead of on the surface 210). Due to this, heat from the wafer W is transferred to the coolant via the dielectric substrate 100, the joining layer made of a resin material, and the base plate 200, and the heat is exhausted to the outside together with the coolant. In other words, the coolant indirectly cools the dielectric substrate 100 via the joining layer made of a resin material and the base plate 200, instead of directly cooling the dielectric substrate 100. In such a configuration, to efficiently cool the wafer W and the like by the coolant, it has been necessary to form the base plate 200 with a metallic material or to mix a filler such as alumina into the joining layer made of a resin material. However, there has been a limit to increasing cooling efficiency by such contrivances.

Particularly, in recent semiconductor manufacturing apparatuses, in order to meet requirements such as multilayering, an output of plasma used for etching and the like has been increasing. For this reason, with the conventional configuration, it is considered that efficiently cooling the wafer W and maintaining a temperature thereof at an appropriate temperature will become even more difficult in the future.

Thus, in the electrostatic chuck 10 according to the present embodiment, as described above, the coolant flow path 250 is formed as the groove G on the surface 210 instead of being formed inside the base plate 200. Due to this, cooling efficiency of the wafer W can be significantly improved as compared with the related art.

In a configuration in which the coolant flow path 250 is formed as the groove G on the surface 210, the base plate 200 does not serve as a path for heat when cooling the wafer W and the dielectric substrate 100. For this reason, it is not necessary to use, as a material of the base plate 200, a material having a high thermal conductivity such as aluminum, for example, and a degree of freedom in selecting a material of the base plate 200 becomes high.

Thus, in the present embodiment, the base plate 200 is not formed of a metallic material but is formed of a ceramic material similar to that of the dielectric substrate 100. Since a coefficient of linear expansion of the base plate 200 can be brought close to, or made identical to a coefficient of linear expansion of the dielectric substrate 100, it is possible to prevent peeling (delamination) at a joining interface, cracking of the dielectric substrate 100, and the like caused by a difference in thermal expansion.

Since a material of the base plate 200 is changed from a conventional metallic material to a ceramic material, a thermal conductivity of the base plate 200 becomes lower as compared with the related art. Due to this, the heat of the base plate 200 is less likely to be taken away by the coolant passing through the coolant flow path 250. That is, a temperature of the coolant passing through the coolant flow path 250 is less likely to increase due to the heat of the base plate 200. As a result, the dielectric substrate 100 can be cooled more efficiently by the low-temperature coolant passing through the coolant flow path 250.

A material contained in the dielectric substrate 100 as a principal component and a material contained in the base plate 200 as a principal component may be different from each other. For example, the dielectric substrate 100 may be formed of a material containing alumina as a principal component, and the base plate 200 may be formed of a material containing aluminum nitride as a principal component. However, to bring the coefficient of linear expansion of the base plate 200 closer to the coefficient of linear expansion of the dielectric substrate 100, it is preferable that both materials be made the same material.

Thus, in the present embodiment, as described above, both of the dielectric substrate 100 and the base plate 200 are constituted of a material containing alumina as a principal component. Due to this, it is possible to further prevent peeling at the joining interface and the like caused by a difference in thermal expansion. A material contained as a common principal component in each of the dielectric substrate 100 and the base plate 200 may be a material other than alumina.

The ceramic material constituting the dielectric substrate 100 and the ceramic material constituting the base plate 200 may be different from each other in purity or in types of impurities. However, if materials that are identical to each other in purity and in types of impurities are used, it is possible to further prevent peeling at the joining interface and the like caused by a difference in thermal expansion.

Regarding conductor layers such as the attraction electrode 130 and the like arranged inside the dielectric substrate 100, accuracy required for a height position, a shape, and the like thereof is considered to become even higher in the future. In view of this point, it is preferable to use alumina at least as a material of the dielectric substrate 100 as in the present embodiment.

As in the present embodiment, in a case where a ceramic material is used as the material of the base plate 200 instead of the metallic material, the base plate 200 cannot be used as one of a pair of RF electrodes (a lower electrode). Thus, as in the present embodiment, the RF electrode 140 needs to be provided inside the dielectric substrate 100. It is also conceivable to provide the RF electrode 140 inside the base plate 200 made of a ceramic material. However, in such a case, a distance between an upper electrode, which is the other one of the RF electrodes, and the RF electrode 140 becomes excessively large, and there is a concern that controllability of plasma may deteriorate. Due to this, from a viewpoint of plasma controllability, it is preferable to provide the RF electrode 140 inside the dielectric substrate 100.

That is, in a case of using a ceramic material as the material of the base plate 200 instead of the metallic material, it is necessary to provide a plurality of conductor layers including at least the attraction electrode 130 and the RF electrode 140 inside the dielectric substrate 100. Also in view of this point, as the material of the dielectric substrate 100, it is preferable to use alumina, which is excellent in sinterability.

In the present embodiment, by adopting the above-described configuration, a thermal expansion difference between the dielectric substrate 100 and the base plate 200 is reduced, and thermal stress applied to the dielectric substrate 100 during processing of the wafer W is also reduced. Due to this, it is possible to make a thickness T of the dielectric substrate 100 thinner than in the related art, and to reduce thermal resistance and impedance of the dielectric substrate 100. The "thickness T of the dielectric substrate 100" refers to a distance from the surface 110 to the surface 120. The thickness T is preferably equal to or smaller than 5 mm, and more preferably equal to or smaller than 4 mm. However, to secure a minimum strength capable of withstanding a processing load and the like at the time of manufacturing, the thickness T is preferably equal to or larger than 0.3 mm, and more preferably equal to or larger than 0.5 mm.

As a method for joining the dielectric substrate 100 and the base plate 200, a method other than solid-phase joining may be used. For example, they may be joined to each other by fusion welding using a laser or an electron beam.

A second embodiment will be described. In the following, features different from those of the first embodiment will be mainly described, and description of features common to those of the first embodiment is omitted as appropriate.

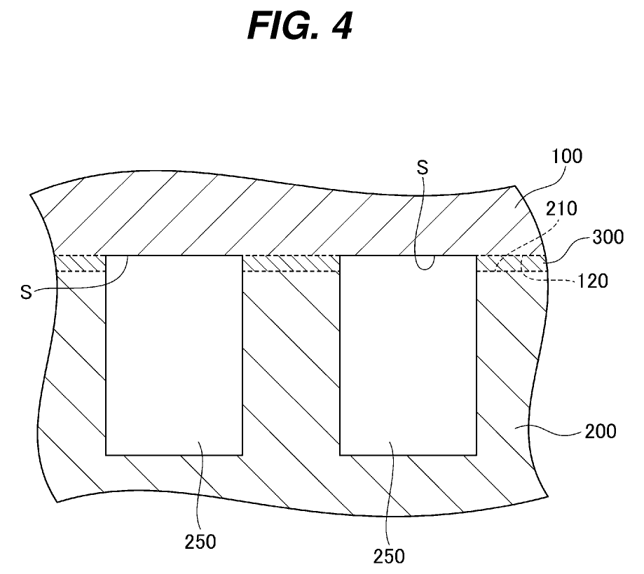

As illustrated in FIG. 4, in the electrostatic chuck 10 according to the present embodiment, the dielectric substrate 100 and the base plate 200 are joined to each other via the joining layer 300. The joining layer 300 is a layer that connects the dielectric substrate 100 and the base plate 200 to each other by solid-phase joining.

For example, the joining layer 300 as described above may be one that has resulted from mutual movement of molecules when the above-described processing of pressurizing and heating is performed in a state where the surface 120 of the dielectric substrate 100, which is a sintered body, and the surface 210 of the base plate 200, which is also a sintered body, are caused to directly abut against each other. Alternatively, the joining layer 300 may be one that has resulted from the above-described processing of pressurizing and heating in a state where some joining material is interposed between the surface 120 and the surface 210, instead of directly causing the surface 120 and the surface 210 to abut against each other.

The joining layer 300 is formed of a material containing alumina. That is, the joining layer 300 contains both of the material contained in the dielectric substrate 100 as a principal component and the material contained in the base plate 200 as a principal component.

Even in a case where the material contained in the dielectric substrate 100 as a principal component and the material contained in the base plate 200 as a principal component are different from each other, it is preferable that the joining layer 300 contain both materials. By joining the dielectric substrate 100 to the base plate 200 via the joining layer 300 made of such a material, it is possible to further increase joining strength at respective joining interfaces. Furthermore, since physical property values of the joining layer 300 (specifically, a coefficient of linear expansion, a thermal conductivity, and the like) can be set to values intermediate between physical property values of the dielectric substrate 100 and physical property values of the base plate 200, an effect can also be obtained in that thermal stress of each part when used in a low-temperature environment or the like can be further alleviated.

The joining layer 300 may be formed in advance as a plate-shaped or powder-shaped member made of a material containing alumina, and the member may thereafter be interposed between the dielectric substrate 100 and the base plate 200 and subjected to processing of pressurizing and heating for a predetermined time to be entirely solid-phase joined. In this case, as a result of occurrence of solid-phase diffusion between the dielectric substrate 100 and the plate-shaped member or the like, and occurrence of solid-phase diffusion between the base plate 200 and the plate-shaped member or the like, respectively, it is possible to obtain the joining layer 300 as illustrated in FIG. 4.

Depending on conditions and methods of solid-phase joining, there may be both a case where a boundary between the joining layer 300 and the dielectric substrate 100 or the like can be clearly visually recognized, and a case where it cannot be clearly visually recognized. Similarly to the first embodiment, there may be a case where the joining layer 300 itself cannot be clearly visually recognized.

In a case where a boundary of the joining layer 300 or the joining layer 300 itself cannot be clearly visually recognized, it is possible to confirm whether the dielectric substrate 100 and the base plate 200 are joined to each other by solid-phase joining by cutting out a sample so as to include both a portion that is clearly the dielectric substrate 100 and a portion that is clearly the base plate 200, and analyzing a portion therebetween. The analysis can be performed by using a well-known elemental analysis method such as EDX analysis, for example.

For example, in a case where it is confirmed that no elements other than Al and O are present at the joining interface between the dielectric substrate 100 and the base plate 200, it is strongly presumed that solid-phase joining has been performed in a state where the surface 120 and the surface 210 are caused to directly abut against each other. Additionally, in a case where other elements are present in addition to Al and O at the above-described joining interface, it is strongly presumed that solid-phase joining has been performed in a state where some joining material is interposed between the surface 120 and the surface 210.

Furthermore, in a case where it is confirmed that an amorphous layer is present at the above-described joining interface by X-ray diffraction, it is strongly presumed that the dielectric substrate 100 and the base plate 200 are joined to each other by solid-phase joining.

As the joining layer 300 that connects the dielectric substrate 100 and the base plate 200, a layer having an aspect different from that described above may be used. For example, the dielectric substrate 100 and the base plate 200 may be joined to each other by using an inorganic brazing material or an inorganic adhesive. As the joining layer 300 as described above, various well-known materials can be used. For example, an inorganic adhesive such as Aron Ceramic manufactured by Toagosei Co., Ltd., SUMICERAM-S manufactured by Asahi Chemical Co., Ltd., and Ceramabond manufactured by Aremco Products Inc. can be used. It is preferable to configure the joining layer 300 with an inorganic adhesive because plasma resistance and a thermal conductivity of the joining layer 300 can be enhanced. Additionally, if corrosion resistance and the like with respect to the coolant can be secured, the joining layer 300 may be formed by using an organic adhesive such as a silicone adhesive, for example.

The joining layer 300 is arranged only at a portion where the surface 120 of the dielectric substrate 100 and the surface 210 of the base plate 200 are opposed to each other. Due to this, also in the present embodiment, the surface 120 is exposed on an inner surface of the coolant flow path 250, and the coolant passing through the coolant flow path 250 flows while being in direct contact with the dielectric substrate 100. In place of such an aspect, it is possible to adopt an aspect in which a portion of the surface 120 opposed to the coolant flow path 250 (a portion denoted by reference sign "S" in FIG. 4) is covered by the joining layer 300 or by a layer similar thereto.

The present embodiments have been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a base plate including a coolant flow path formed therein through which a coolant flows, wherein
the dielectric substrate is joined to the base plate, and
the coolant flow path is a groove formed on a surface on the dielectric substrate side of the base plate.

2. The electrostatic chuck according to claim 1, wherein the dielectric substrate is formed of a ceramic material, and the base plate is also formed of a ceramic material.

3. The electrostatic chuck according to claim 2, wherein a material contained in the dielectric substrate as a principal component and a material contained in the base plate as a principal component are the same.

4. The electrostatic chuck according to claim 3, wherein both of the dielectric substrate and the base plate contain alumina as a principal component.

5. The electrostatic chuck according to claim 4, wherein a thickness of the dielectric substrate is equal to or smaller than 5 mm.

6. The electrostatic chuck according to claim 1, wherein the dielectric substrate and the base plate are joined to each other by solid-phase joining.

7. The electrostatic chuck according to claim 1, wherein a joining layer is provided between the dielectric substrate and the base plate.

8. The electrostatic chuck according to claim 7, wherein the joining layer connects the dielectric substrate and the base plate by solid-phase joining.

9. The electrostatic chuck according to claim 8, wherein
the joining layer contains both of
a material contained in the dielectric substrate as a principal component, and
a material contained in the base plate as a principal component.

10. The electrostatic chuck according to claim 1, wherein the dielectric substrate contains highly pure alumina having a purity of 99.5% or more as a principal component.

11. The electrostatic chuck according to claim 1, wherein a conductor layer is provided inside the dielectric substrate.

12. The electrostatic chuck according to claim 11, wherein a plurality of the conductor layers are provided at height positions different from each other.
